(19) United States
(12) Patent Application Publication
(10) Pub. No.: US 2026/0160595 A1
(43) Pub. Date: Jun. 11, 2026

(54) PHOTO-DETECTING APPARATUS

(71) Applicant: Artilux, Inc., Menlo Park, CA (US)

(72) Inventor: Che-Fu Liang, Zhubei City (TW)

(21) Appl. No.: 19/413,740

(22) Filed: Dec. 9, 2025

Related U.S. Application Data
(60) Provisional application No. 63/729,468, filed on Dec. 9, 2024.

(51) Int. Cl. G01J 1/46; H03K 17/20; H04B 10/69; G01J 1/44

(52) U.S. Cl. CPC G01J 1/46; H03K 17/20; H04B 10/69; G01J 2001/446

(57) ABSTRACT

A photo-detecting apparatus having a high detection speed is configured for use in a variety of optical applications. Such a photo-detecting apparatus can include a light receiver configured to convert an incident light to an electrical signal. The photo-detecting apparatus can also include a converting circuit coupling to the light receiver to convert the electrical signal into an output voltage through an integration operation, wherein the converting circuit comprises a first integral block and a second integral block. The photo-detecting apparatus can also include a readout circuit coupling to the converting circuit to output the output voltage from the converting circuit. While the first integral block performs the integration operation, the second integral block outputs the output voltage. While the first integral block outputs the output voltage, the second integral block performs the integration operation.

### RELATED APPLICATIONS

The subject application claims the benefit of priority to United States Provisional Patent Application No. 63/729,468 filed on December 9, 2024, entitled “Photo-Detecting Apparatus,” which is incorporated by reference herein in its entirety for all purposes.

### FIELD

The present disclosure relates generally to photo-detecting technology for use with optical communication systems. More particularly, the present disclosure relates to a photo-detecting apparatus, and more particularly, to a photo-detecting apparatus with high detection speed.

### BACKGROUND

Photo-detecting apparatuses may be used to detect incident light and convert the incident light to an electrical signal that may be further processed by other circuitry. Photo-detecting apparatuses may be used in consumer electronics products, image sensors, data communications, time-of-flight (ToF), light detection and ranging (LiDAR), medical devices, and other suitable applications. In some applications, a photo-detecting apparatus needs to have high detection speed to enhance detection efficiency.

### SUMMARY

Aspects and advantages of embodiments of the present disclosure will be set forth in part in the following description, or may be learned from the description, or may be learned through practice of the embodiments.

One example aspect of the present disclosure is directed to a photo-detecting apparatus. The photo-detecting apparatus includes a light receiver configured to convert an incident light to an electrical signal. The photo-detecting apparatus also includes a converting circuit coupling to the light receiver to convert the electrical signal into an output voltage through an integration operation, wherein the converting circuit includes a first integral block and a second integral block. The photo-detecting apparatus also includes a readout circuit coupling to the converting circuit to output the output voltage from the converting circuit. While the first integral block has an electrical connection to the light receiver to perform the integration operation, the second integral block has an electrical connection to the readout circuit to output the output voltage. While the first integral block has an electrical connection to the readout circuit to output the output voltage, the second integral block has an electrical connection to the light receiver to perform the integration operation.

In some implementations, the photo-detecting apparatus also includes a first integral control signal and a second integral control signal applying to the converting circuit to control the electrical connection of the first integral block and the electrical connection of the second integral block.

In some implementations, the second integral control signal has an opposite polarity to the first integral control signal.

In some implementations, the first integral block includes a first capacitor, and the first capacitor is configured to electrically connect to the light receiver through a first transistor according to the first integral control signal.

In some implementations, the first integral block includes a first capacitor, and the first capacitor is configured to electrically connect to the readout circuit through a second transistor according to the second integral control signal.

In some implementations, the second integral block includes a second capacitor, and the second capacitor is configured to electrically connect to the light receiver through a third transistor according to the second integral control signal.

In some implementations, the second integral block includes a second capacitor, the second capacitor is configured to electrically connect to the readout circuit through a fourth transistor according to the first integral control signal.

In some implementations, the readout circuit includes a source-follower transistor coupling to the converting circuit to receive the output voltage and a line-select transistor coupling to the source-follower transistor to output the output voltage.

In some implementations, the line-select transistor includes a first node coupling to the source-follower transistor, a second node configured to output the output voltage, and a third node configured to receive a readout control signal to determine whether the readout circuit outputs the output voltage from the converting circuit.

In some implementations, the photo-detecting apparatus also includes a reset circuit coupling to the converting circuit to reset the converting circuit before each integration operation.

In some implementations, the light receiver includes a photodiode configured to absorb the incident light and a switch configured to output the electrical signal.

In some implementations, the photodiode includes a light-absorption material supported by a semiconductor substrate, and the light- absorption material is different from a material of the semiconductor substrate.

Another example implementation of the disclosed technology is directed to method of using a photo-detecting apparatus to detect an incident light, the photo-detecting apparatus including a reset circuit, a first integral block, a second integral block, and a readout circuit. The method includes entering a first operation mode, the first operation mode including: performing, by the reset circuit, a reset operation on the first integral block; and performing, by the first integral block, an integration operation to provide a first output voltage in response to the incident light, while the readout circuit outputs a second output voltage from the second integral block. The method also includes entering a second operation mode, the second operation mode including: performing, by the reset circuit, the reset operation on the second integral block; and performing, by the second integral block, the integration operation to provide the second output voltage in response to the incident light, while the readout circuit outputs the first output voltage from the first integral block.

In some implementations, the reset operation is controlled by a reset control signal.

In some implementations, the first integral block includes a first capacitor, the reset operation includes charging the first capacitor to a source voltage.

In some implementations, the integration operation includes discharging the first capacitor from the source voltage to the first output voltage.

In some implementations, the first operation mode includes electrically connecting the first integral block to a light receiver and the reset circuit, and electrically connecting the second integral block to the readout circuit.

In some implementations, the second operation mode includes electrically connecting the second integral block to a light receiver and the reset circuit, and electrically connecting the first integral block to the readout circuit.

Another example implementation of the disclosed technology includes an optical communication system. The optical communication system includes an optical channel configured to transmit a plurality of optical signals. The optical communication system also includes an optical receiving module including a plurality of photo-detecting apparatuses to receive the plurality of optical signals. Each photo-detecting apparatus includes a light receiver configured to convert an incident light to an electrical signal. Each photo-detecting apparatus also includes a converting circuit coupling to the light receiver to convert the electrical signal into an output voltage through an integration operation, wherein the converting circuit includes a first integral block and a second integral block. Each photo-detecting apparatus also includes a readout circuit coupling to the converting circuit to output the output voltage from the converting circuit. While the first integral block has an electrical connection to the light receiver to perform the integration operation, the second integral block has an electrical connection to the readout circuit to output the output voltage. While the first integral block has an electrical connection to the readout circuit to output the output voltage, the second integral block has an electrical connection to the light receiver to perform the integration operation.

In some implementations, the optical communication system also includes a plurality of light transmitters coupling to the optical channel to transmit the plurality of optical signals.

Another example implementation of the disclosed technology is directed to a photo-detecting apparatus. The photo-detecting apparatus includes a light receiver configured to convert an incident light to an electrical signal. The photo-detecting apparatus also includes a readout circuit configured to output an output voltage in response to the electrical signal. The photo-detecting apparatus also includes a first capacitor coupling to the light receiver through a first transistor and coupling to the readout circuit through a second transistor. The photo-detecting apparatus also includes a second capacitor coupling to the light receiver through a third transistor and coupling to the readout circuit through a fourth transistor.

Other example aspects of the present disclosure are directed to systems, methods, apparatuses, sensors, computing devices, tangible non-transitory computer-readable media, and memory devices related to the described technology.

These and other features, aspects and advantages of various embodiments will become better understood with reference to the following description and appended claims. The accompanying drawings, which are incorporated in and constitute a part of this specification, illustrate embodiments of the present disclosure, and together with the description, serve to explain the related principles.

### BRIEF DESCRIPTION OF THE DRAWINGS

The foregoing aspects and many of the advantages of this application will become more readily appreciated as the same becomes better understood by reference to the following detailed description when taken in conjunction with the accompanying drawings:

FIG. 1A shows a circuit diagram of a photo-detecting apparatus in accordance with one embodiment of the present disclosure.

FIG. 1B shows an operation mode of a photo-detecting apparatus in accordance with an embodiment of the present disclosure.

FIG. 1C shows another operation mode of a photo-detecting apparatus in accordance with an embodiment of the present disclosure.

FIG. 2A shows a timing diagram of operating a photo-detecting apparatus in accordance with an embodiment of the present disclosure.

FIG. 2B shows the steps of operation of a method of using a photo-detecting apparatus in accordance with an embodiment of the present disclosure.

FIG. 3A shows a circuit diagram of a photo-detecting apparatus in accordance with another embodiment of the present disclosure.

FIG. 3B shows a circuit diagram of a photo-detecting apparatus in accordance with another embodiment of the present disclosure.

FIG. 4A shows a circuit diagram of a photo-detecting apparatus in accordance with another embodiment of the present disclosure.

FIG. 4B shows a circuit diagram of a photo-detecting apparatus in accordance with another embodiment of the present disclosure.

FIG. 5 shows an image sensor in accordance with an embodiment of the present disclosure.

FIG. 6 shows an optical communication system in accordance with an embodiment of the present disclosure.

### DETAILED DESCRIPTION

The following embodiments accompany the drawings to illustrate the concept of the present disclosure. In the drawings or descriptions, similar or identical parts use the same reference numerals, and in the drawings, the shape, thickness, or height of the element can be reasonably expanded or reduced. The embodiments listed in the present application are only used to illustrate the present application and are not used to limit the scope of the present application. Any obvious modification or change made to the present application does not depart from the spirit and scope of the present application.

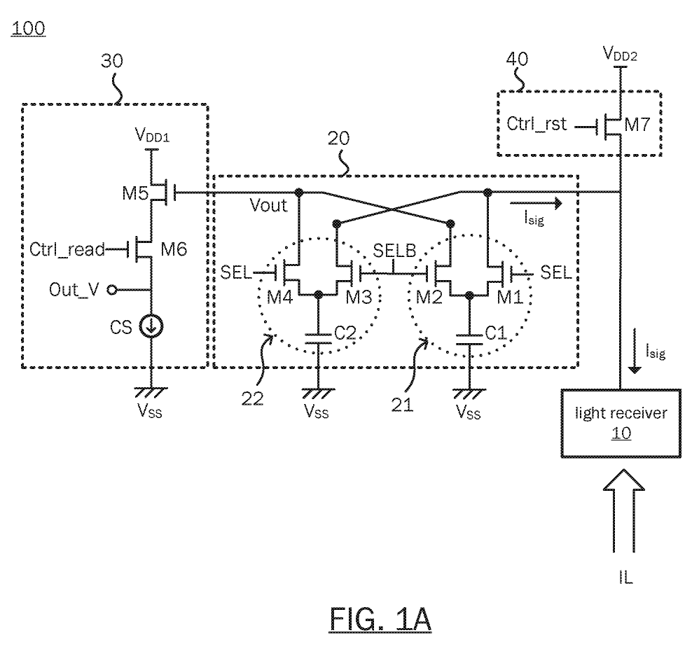

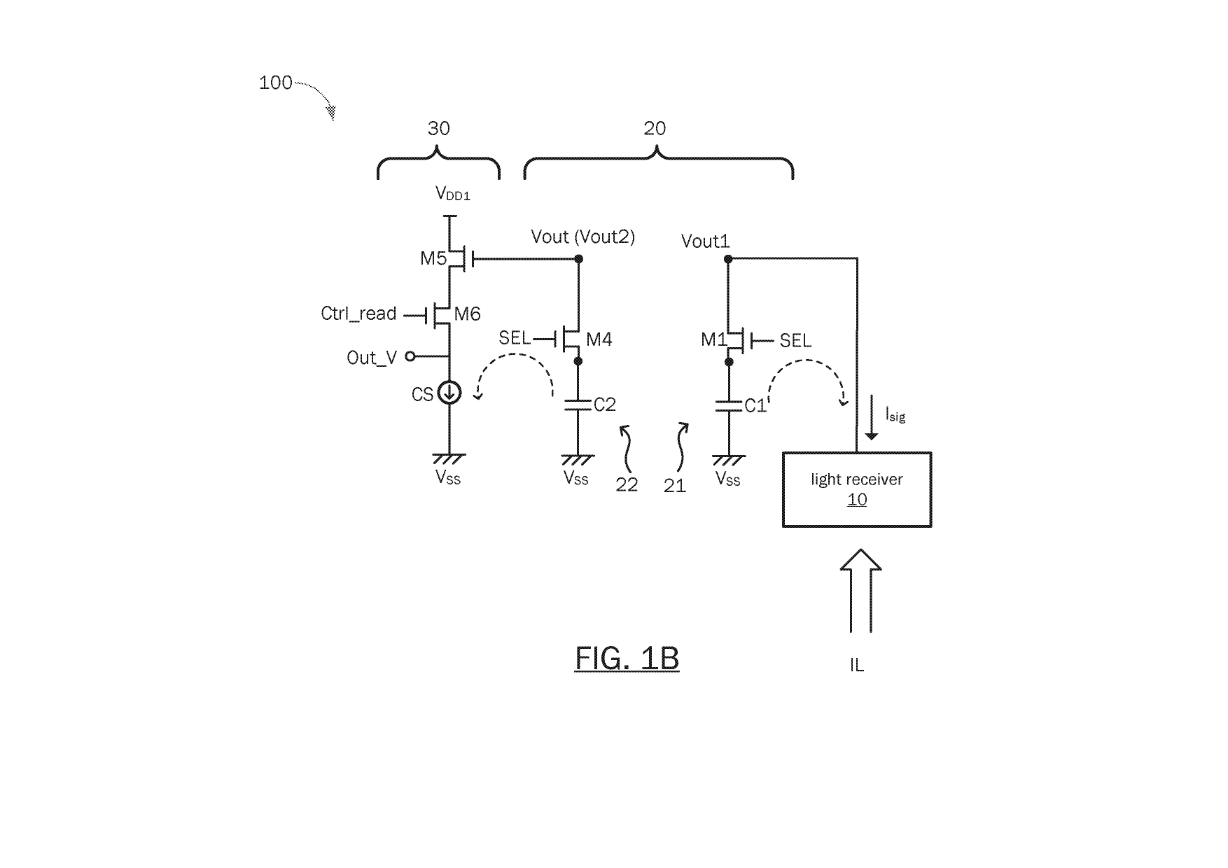

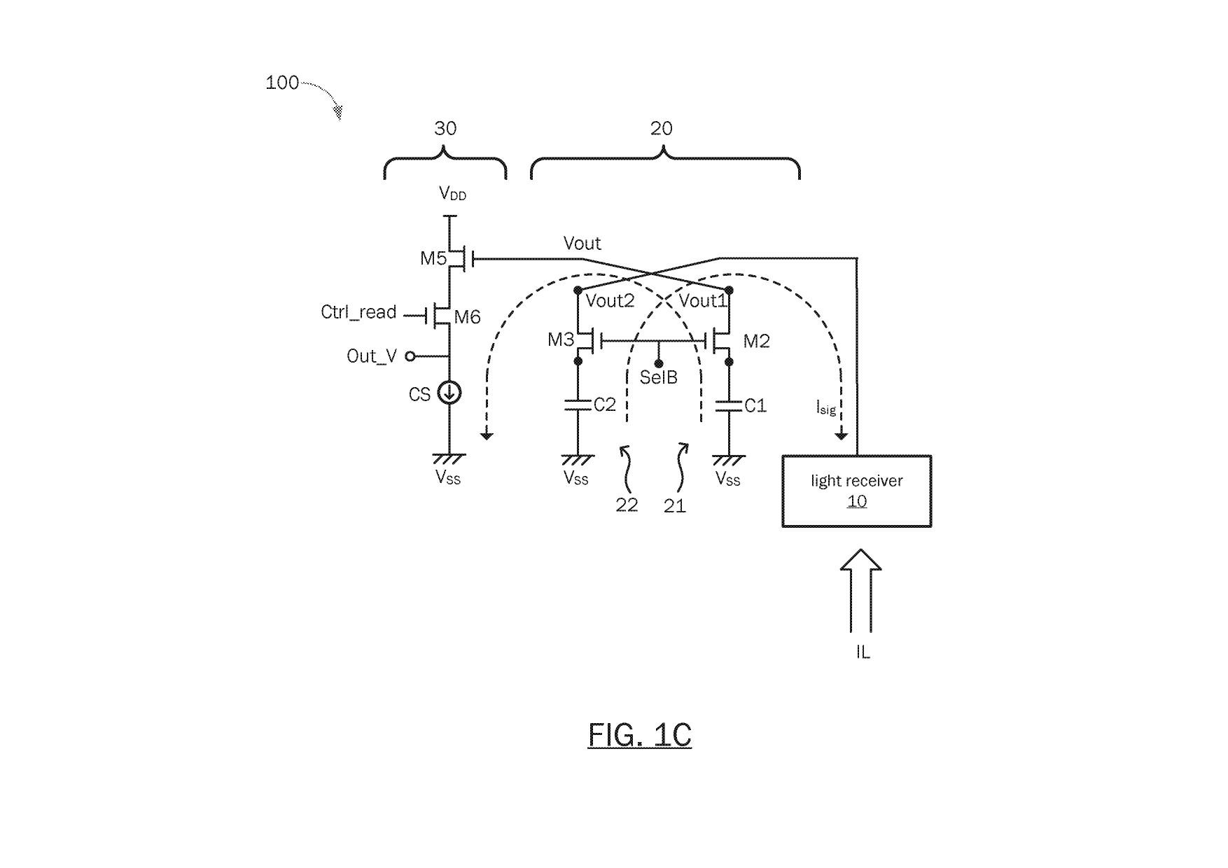

FIG. 1A shows a circuit diagram of a photo-detecting apparatus in accordance with one embodiment of the present disclosure. The photo-detecting apparatus 100 includes a light receiver 10, a converting circuit 20 coupling to the light receiver 10, a readout circuit 30 coupling to the converting circuit 20, and a reset circuit 40 coupling to the light receiver 10 and the converting circuit 20. The light receiver 10 is configured to convert an incident light IL to an electrical signal Isig, where the electrical signal Isig is a photo-current in response to the intensity of the incident light IL.

The converting circuit 20 is configured to convert the electrical signal Isig into an output voltage VOUT through an integration operation. The converting circuit 20 includes a first integral block 21 and a second integral block 22 that are alternately electrically connected to the light receiver 10 and the readout circuit 30. While the first integral block 21 has an electrical connection (i.e., is electrically connected) to the light receiver 10 to perform the integration operation, the second integral block 22 has an electrical connection (i.e., is electrically connected) to the readout circuit 30 to output the output voltage VOUT. On the contrary, while the first integral block 21 has an electrical connection (i.e., is electrically connected) to the readout circuit 30 to output the output voltage VOUT, the second integral block 22 has an electrical connection (i.e., is electrically connected) to the light receiver 10 to perform the integration operation. When the first integral block 21 is connected to the light receiver 10 to perform the integration operation, the first integral block 21 is electrically isolated from the readout circuit 30. When the second integral block 22 is connected to the light receiver 10 to perform the integration operation, the second integral block 22 is electrically isolated from the readout circuit 30. A first integral control signal SEL and a second integral control signal SELB can apply to the converting circuit 20 to control the electrical connection of the first integral block 21 and the electrical connection of the second integral block 22.

The first integral block 21 includes a first capacitor C1, a first transistor M1, and a second transistor M2. The first transistor M1 includes a first node (e.g., the drain of an NMOS) coupling to the reset circuit 40 and the light receiver 10, a second node (e.g., the source of an NMOS) coupling to the first capacitor C1, and a third node (e.g., the gate of an NMOS) configured to receive the first integral control signal SEL. The second transistor M2 includes a first node (e.g., the drain of an NMOS) coupling to the readout circuit 30 to output the output voltage VOUT, a second node (e.g., the source of an NMOS) coupling to the first capacitor C1, and a third node (e.g., the gate of an NMOS) configured to receive the second integral control signal SELB, where the second integral control signal SELB has an opposite polarity to the first integral control signal SEL. The first integral control signal SEL and the second integral control signal SELB can determine that the first capacitor C1 electrically connects to the light receiver 10 or the readout circuit 30 by controlling the switches of the first transistor M1 and the second transistor M2. For example, the first integral control signal SEL can control the first transistor M1 to turn on so that the first capacitor C1 can electrically connect to the light receiver 10 and the reset circuit 40 through the first transistor M1 according to the first integral control signal SEL. Contrarily, the first integral control signal SEL can control the first transistor M1 to turn off so that the first capacitor C1 can electrically isolate from the light receiver 10 and the reset circuit 40 through the first transistor M1 according to the first integral control signal SEL. The second integral control signal SELB can control the second transistor M2 to turn on so that the first capacitor C1 can electrically connect to the readout circuit 30 through the second transistor M2 according to the second integral control signal SELB. Contrarily, the second integral control signal SELB can control the second transistor M2 to turn off so that the first capacitor C1 can electrically isolate from the readout circuit 30 through the second transistor M2 according to the second integral control signal SELB.

The second integral block 22 includes a second capacitor C2, a third transistor M3, and a fourth transistor M4. The third transistor M3 includes a first node (e.g., the drain of an NMOS) coupling to the reset circuit 40 and the light receiver 10, a second node (e.g., the source of an NMOS) coupling to the second capacitor C2, and a third node (e.g., the gate of an NMOS) configured to receive the second integral control signal SELB. The fourth transistor M4 includes a first node (e.g., the drain of an NMOS) coupling to the readout circuit 30 to output the output voltage VOUT, a second node (e.g., the source of an NMOS) coupling to the second capacitor C2, and a third node (e.g., the gate of an NMOS) configured to receive the first integral control signal SEL, where the second integral control signal SELB has an opposite polarity to the first integral control signal SEL. The first integral control signal SEL and the second integral control signal SELB can determine that the second capacitor C2 electrically connects to the light receiver 10 or the readout circuit 30 by controlling the switches of the third transistor M3 and the fourth transistor M4. For example, the second integral control signal SELB can control the third transistor M3 to turn on so that the second capacitor C2 can electrically connect to the light receiver 10 and the reset circuit 40 through the third transistor M3 according to the second integral control signal SELB. Contrarily, the second integral control signal SELB can control the third transistor M3 to turn off so that the second capacitor C2 can electrically isolate from the light receiver 10 and the reset circuit 40 through the third transistor M3 according to the second integral control signal SELB. The first integral control signal SEL can control the fourth transistor M4 to turn on so that the second capacitor C2 can electrically connect to the readout circuit 30 through the fourth transistor M4 according to the first integral control signal SEL. Contrarily, the first integral control signal SEL can control the fourth transistor M4 to turn off so that the second capacitor C2 can electrically isolate from the readout circuit 30 through the fourth transistor M4 according to the first integral control signal SEL.

The first capacitor C1 includes a first node coupling to the first transistor M1 and the second transistor M2, and a second node coupling to a common voltage VSS (e.g., the ground). The second capacitor C2 includes a first node coupling to the third transistor M3 and the fourth transistor M4, and a second node coupling to the common voltage VSS (e.g., the ground).

The readout circuit 30 is configured to read out the output voltage VOUT from the converting circuit 20 through the terminal Out_V according to a readout control signal Ctrl_read. The readout circuit 30 includes a source-follower transistor M5, a line- select transistor M6, and a current source CS. The source-follower transistor M5 includes a first node (e.g., the drain of an NMOS) coupling to a power supply to receive a source voltage VDD1, a second node (e.g., the source of an NMOS) coupling to the line-select transistor M6, and a third node (e.g., the gate of an NMOS) coupling to the converting circuit 20 to receive the output voltage VOUT from the converting circuit 20. The line-select transistor M6 includes a first node (e.g., the drain of an NMOS) coupling to the second node of the source-follower transistor M5, a second node (e.g., the source of an NMOS) coupling to the current source CS and the terminal Out_V to output the output voltage VOUT, and a third node (e.g., the gate of an NMOS) configured to receive the readout control signal Ctrl_read. The readout control signal Ctrl_read is used to control whether the readout circuit outputs the output voltage from the converting circuit 20. The current source CS includes a first node coupling to the line-select transistor M6, and a second node coupling to the common voltage VSS (e.g., the ground). In an implementation, the readout control signal Ctrl_read can couple to a row selector or a column selector, and the terminal Out_V can couple to a bit-line for an image sensor.

The reset circuit 40 includes a reset transistor M7, which includes a first node (e.g., the drain of an NMOS) coupling to a power supply to receive a source voltage VDD2, a second node (e.g., the source of an NMOS) coupling to the light receiver 10 and the converting circuit 20, and a third node (e.g., the gate of an NMOS) configured to receive a reset control signal Ctrl_rst to reset the converting circuit 20 before each integration operation. The source voltage VDD2 for the reset circuit 40 can be the same or different from the voltage VDD1 for the readout circuit 30.

In some implementations, the first transistor M1, the second transistor M2, the third transistor M3, the fourth transistor M4, the source-follower transistor M5, the line-select transistor M6, and the reset transistor M7 can be implemented by NMOS transistors and/or PMOS transistors.

During the operation of the photo-detecting apparatus 100, the reset circuit 40 first resets the converting circuit 20. Then, the converting circuit 20 starts to perform the integration operation to provide the output voltage VOUT. After the integration operation, the readout circuit 30 reads the output voltage VOUT onto the terminal Out_V. The converting circuit 20 has at least two integral blocks (e.g., the first integral block 21 and the second integral block 22) that can alternatively perform the integration operations to output the output voltage VOUT, thereby the detection speed of the photo-detecting apparatus 100 can be increased. For example, the photo-detecting apparatus 100 can operate in at least two modes. One operation mode is that the first integral block 21 performs the integration operation while the readout circuit 30 performs the readout operation on the second integral block 22 to output the output voltage. The other operation mode is that the readout circuit 30 performs the readout operation on the first integral block 21 to output the output voltage while the second integral block 22 performs the integration operation. In this way, the photo-detecting apparatus 100 can simultaneously perform the integration operation and the readout operation to achieve high-speed detection.

FIG. 1B shows an operation mode of a photo-detecting apparatus in accordance with one embodiment of the present disclosure. When the first integral block 21 of the converting circuit 20 needs to perform the integration operation, referring back to FIG. 1A, a reset control signal Ctrl_rst applies to the reset transistor M7 to activate the reset circuit 40 so that the reset transistor M7 operates in the saturation region or triode region to reset the first integral block 21. In other words, the reset circuit 40 resets the first output voltage Vout1 of the first integral block 21 to VDD2. The first integral control signal SEL is set to be greater than the threshold voltages of the first transistor M1 and the fourth transistor M4 to turn on the first transistor M1 and the fourth transistor M4. The second integral control signal SELB has an opposite polarity to the first integral control signal SEL and is set to be less than the threshold voltages of the second transistor M2 and the third transistor M3 to turn off the second transistor M2 and the third transistor M3. Thereby, the first integral block 21 (or the first capacitor C1) electrically connects to the reset circuit 40 and the light receiver 10 and electrically isolates from the readout circuit 30. The second integral block 22 (or the second capacitor C2) electrically connects to the readout circuit 30 and electrically isolates from the reset circuit 40 and the light receiver 10.

Then, a current flows through the reset transistor M7 and the first transistor M1 to the first capacitor C1, charging the first capacitor C1 to the source voltage VDD2 to perform the reset operation. Referring to FIG. 1B, once the charging of the first capacitor C1 is completed, indicating that the reset operation is completed, the reset circuit 40 (or the reset transistor M7) is turned off by controlling the reset control signal Ctrl_rst. In order to facilitate the explanation of the subsequent operations of the first integral block 21 and the second integral block 22, the reset circuit 40 is not shown in FIG. 1B. Since the second integral control signal SELB is set to turn off the second transistor M2 and the third transistor M3, the second transistor M2 and the third transistor M3 can be ignored and are not shown in FIG. 1B for convenience of explanation. During the detection operation, the light receiver 10 absorbs the incident light IL, and the photo-current generated by the light receiver 10 causes the electrical signal Isig. The electrical signal Isig directly flows through the first integral block 21 to perform the integration operation. During the integration operation on the first integral block 21, the electrical signal Isig flows through the first capacitor C1 and the first transistor M1 to discharge the first capacitor C1. As a result, the voltage across the first capacitor C1 will drop when the incident light IL comes in. After a predetermined time of integration operation, the voltage across the first capacitor C1 will drop to a settled value to provide the first output voltage Vout1 of the first integral block 21, which can be read out during the subsequent readout operation.

During the integration operation of the first integral block 21, the readout circuit 30 can simultaneously perform a readout operation on the second integral block 22. Referring to FIG. 1B, when the first integral block 21 performs the integration operation, the second integral block 22 is electrically isolated from the light receiver 10, and the second output voltage Vout2 of the second integral block 22 is coupled to the output of the converting circuit 20 as the output voltage Vout for the readout operation. According to the readout control signal Ctrl_read, the second output voltage Vout2 of the second integral block 22 will be the output voltage and read onto the terminal Out_V through the source-follower transistor M5 and the line-select transistor M6.

FIG. 1C shows another operation mode of a photo-detecting apparatus in accordance with an embodiment of the present disclosure. When the second integral block 22 of the converting circuit 20 needs to perform the integration operation, referring back to FIG. 1A, a reset control signal Ctrl_rst applies to the reset transistor M7 to activate the reset circuit 40 so that the reset transistor M7 operates in the saturation region or triode region to reset the second integral block 22. In other words, the reset circuit 40 resets the second output voltage Vout2 of the second integral block 22 to VDD2. The second integral control signal SELB is set to be greater than the threshold voltages of the second transistor M2 and the third transistor M3 to turn on the second transistor M2 and the third transistor M3. The first integral control signal SEL has an opposite polarity to the second integral control signal SELB and is set to be less than the threshold voltages of the first transistor M1 and the fourth transistor M4 to turn off the first transistor M1 and the fourth transistor M4. Thereby, the second integral block 22 (or the second capacitor C2) electrically connects to the reset circuit 40 and the light receiver 10 and electrically isolates from the readout circuit 30. The first integral block 21 (or the first capacitor C1) electrically connects to the readout circuit 30 and electrically isolates from the reset circuit 40 and the light receiver 10.

Then, a current flows through the reset transistor M7 and the third transistor M3 to the second capacitor C2, charging the second capacitor C2 to the source voltage VDD2 to perform the reset operation. Referring to FIG. 1C, once the charging of the second capacitor C2 is completed, indicating that the reset operation is completed, the reset circuit 40 (or the reset transistor M7) is turned off by controlling the reset control signal Ctrl_rst. In order to facilitate the explanation of the subsequent operations of the first integral block 21 and the second integral block 22, the reset circuit 40 is not shown in FIG. 1C. Since the first integral control signal SEL is set to turn off the first transistor M1 and the fourth transistor M4, the first transistor M1 and the fourth transistor M4 can be ignored and are not shown in FIG. 1C for convenience of explanation. During the detection operation, the light receiver 10 absorbs the incident light IL, and the photo-current generated by the light receiver 10 causes the electrical signal Isig. The electrical signal Isig directly flows through the second integral block 22 to perform the integration operation. During the integration operation on the second integral block 22, the electrical signal Isig flows through the second capacitor C2 and the third transistor M3 to discharge the second capacitor C2. As a result, the voltage across the second capacitor C2 will drop when the incident light IL comes in. After a predetermined time of integration operation, the voltage across the second capacitor C2 will drop to a settled value to provide the output voltage Vout2 of the second integral block 22, which can be read out during the subsequent readout operation.

During the integration operation of the second integral block 22, the readout circuit 30 can simultaneously perform a readout operation on the first integral block 21. Referring to FIG. 1C, when the second integral block 22 performs the integration operation, the first integral block 21 is electrically isolated from the light receiver 10, and the first output voltage Vout1 of the first integral block 21 is coupled to the output of the converting circuit 20 as the output voltage Vout for the readout operation. According to the readout control signal Ctrl_read, the first output voltage Vout1 of the first integral block 21 will be the output voltage and read onto the terminal Out_V through the source-follower transistor M5 and the line-select transistor M6. By repeating the above operation modes shown in FIGS. 1B and 1C, the photo-detecting apparatus 100 can achieve high-speed light detection.

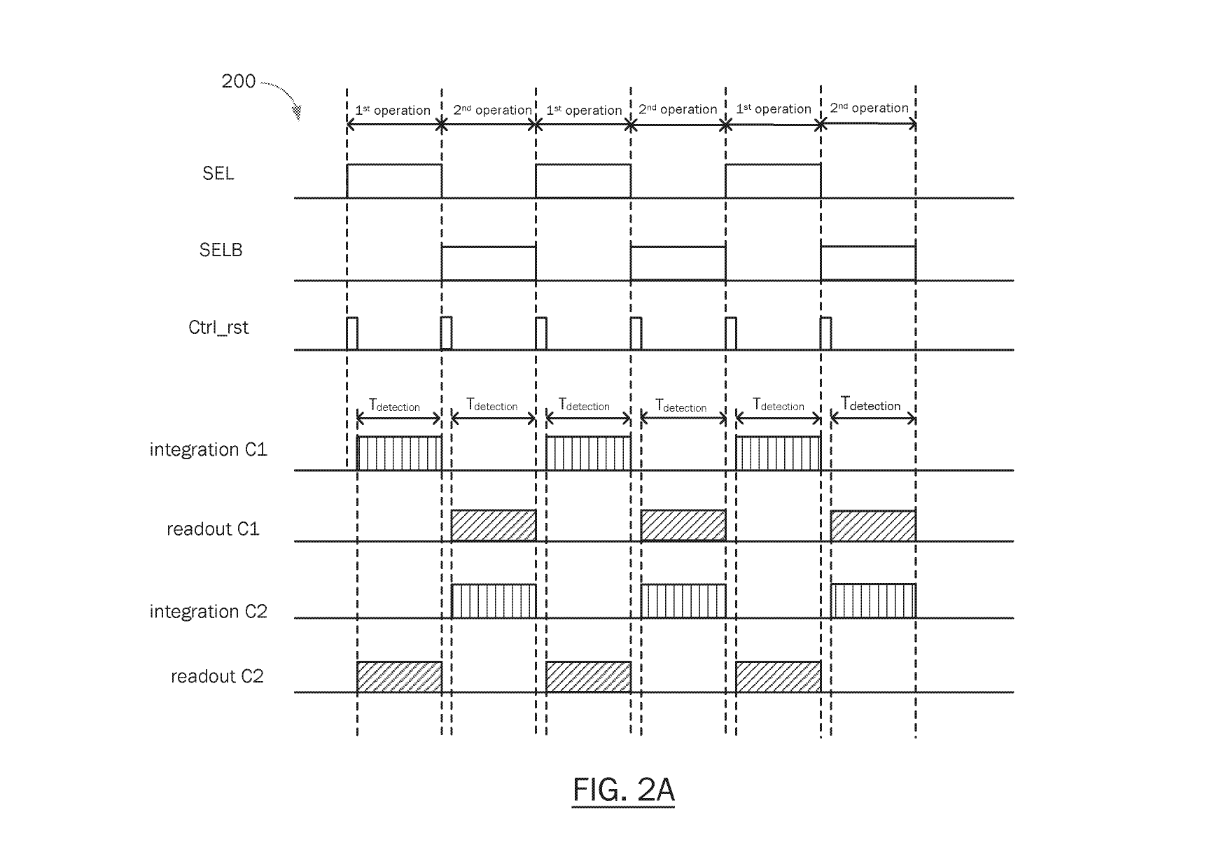

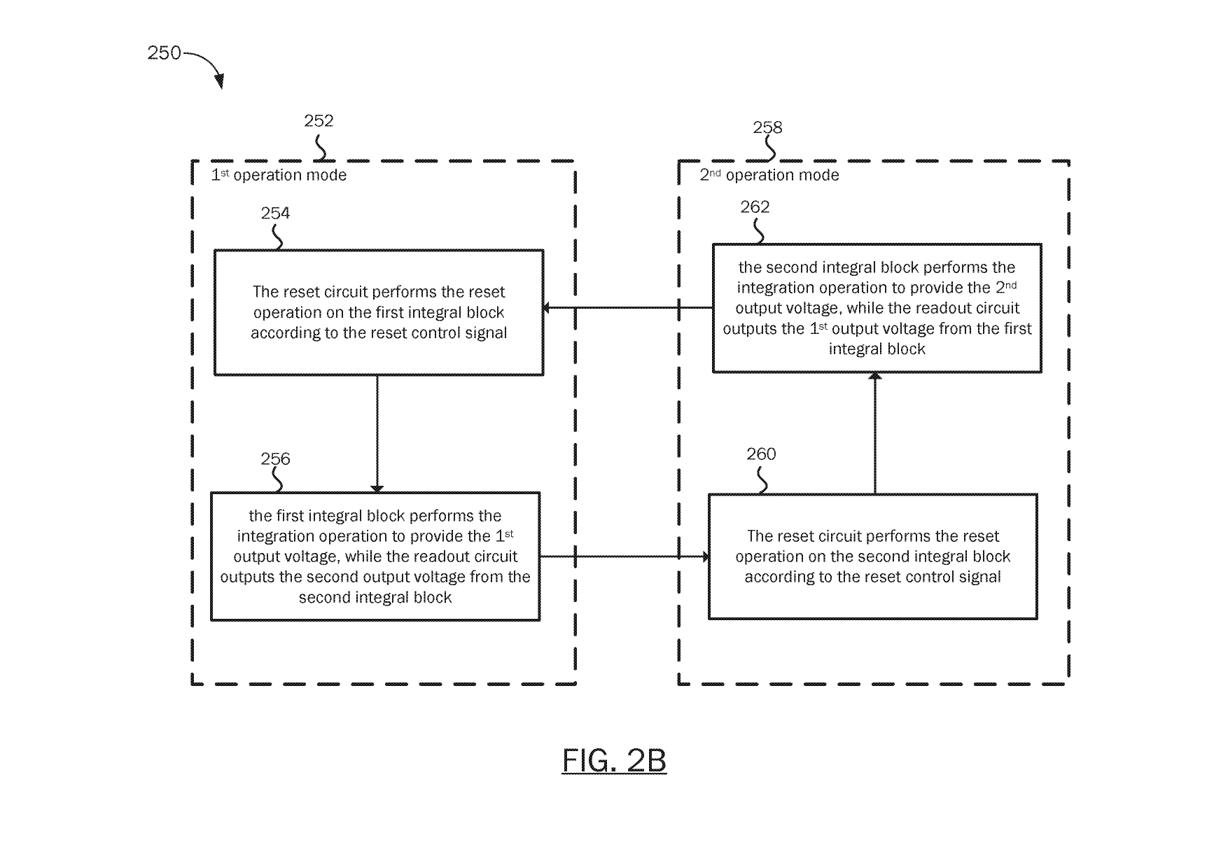

FIG. 2A shows a timing diagram 200 of operating a photo-detecting apparatus in accordance with an embodiment of the present disclosure. This timing diagram can detail the operation of the photo-detecting apparatus 100, which can include at least first (1^{st}) operation mode and second (2^{nd}) operation mode that operate alternatively. For example, in the 1^{st} operation mode, the first capacitor C1 (or the first integral block 21) performs an integration operation, while a readout operation is performed on the second capacitor C2 (or the first integral block 21) by the readout circuit. In the 2^{nd} operation mode, a readout operation is performed on the first capacitor C1 (or the first integral block 21) by the readout circuit, while the second capacitor C2 (or the first integral block 21) performs an integration operation. As shown in FIGS. 1A and 2A, during the 1^{st} operation mode, the first integral control signal SEL is set to turn on the first transistor M1 and the fourth transistor M4, while the second integral control signal SELB is set to the opposite polarity of the first integral control signal SEL to turn off the second transistor M2 and the third transistor M3. Thereby, the first integral block 21 electrically connects to the light receiver 10 and the reset circuit 40 and electrically isolates from the readout circuit 30. The second integral block 22 electrically connects to the readout circuit 30 and electrically isolates from the light receiver 10 and the reset circuit 40. Initially, the reset circuit 40 performs a reset operation on the first integral block 21 (or the first capacitor C1) according to the reset control signal Ctrl_rst, recharging the first capacitor C1 to VDD2. Once the reset operation on the first capacitor C1 is completed and the light receiver 10 detects the incident light IL, the first capacitor C1 will be discharged as the electrical signal Isig generates. The first integral block 21 performs an integration operation while the first capacitor C1 is discharging, thereby providing a first output voltage Vout1 after the voltage across the first capacitor C1 drops to a stable value in response to the intensity of the incident light IL. Since the second integral block 22 electrically connects to the readout circuit 30, when the first integral block 21 performs the integration operation, the readout circuit 30 simultaneously performs the readout operation on the second integral block 22 to output the second output voltage Vout2 of the second integral block 22 to the terminal Out_V.

As shown in FIGS. 1A and 2A, during the 2^{nd} operation mode, the second integral control signal SELB is set to turn on the second transistor M2 and the third transistor M3, while the first integral control signal SEL is set to the opposite polarity of the second integral control signal SELB to turn off the first transistor M1 and the fourth transistor M4. Thereby, the second integral block 22 electrically connects to the light receiver 10 and the reset circuit 40 and electrically isolates from the readout circuit 30. The first integral block 21 electrically connects to the readout circuit 30 and electrically isolates from the light receiver 10 and the reset circuit 40. Initially, the reset circuit 40 performs a reset operation on the second integral block 22 (or the second capacitor C2) according to the reset control signal Ctrl_rst, recharging the second capacitor C2 to VDD2. Once the reset operation on the second capacitor C2 is completed and the light receiver 10 detects the incident light IL, the second capacitor C2 will be discharged as the electrical signal Isig generates. The second integral block 22 performs an integration operation while the second capacitor C2 is discharging, thereby providing a second output voltage Vout2 after the voltage across the second capacitor C2 drops to a stable value in response to the intensity of the incident light IL. Since the first integral block 21 electrically connects to the readout circuit 30, when the second integral block 22 performs the integration operation, the readout circuit 30 simultaneously performs the readout operation on the first integral block 21 to output the first output voltage Vout1 of the first integral block 21 to the terminal Out_V.

Whether the first integral block 21 performs the integration operation or the second integral block 22 performs the integration operation, the duration of each integration operation is the detection time Tdetection or the exposure time of the photo-detecting apparatus. As shown in FIG. 2A, since the converting circuit 20 has at least two integral blocks that can perform integration operations in turn, the converting circuit 20 can perform the integration operation and the readout operation at the same time, thereby maximizing the detection time Tdetection or exposure time of the photo-detecting apparatus. Compared with other photo-detecting apparatuses in which the integration operation and the readout operation are performed sequentially, the photo-detecting apparatus with this configuration can increase the detection speed.

FIG. 2B shows the steps of operation of a method 250 of using a photo-detecting apparatus in accordance with an embodiment of the present disclosure. When the photo-detecting apparatus operates in the first operation mode 252, method 250 includes operation 254 wherein the reset circuit first performs the reset operation on the first integral block. Once the reset operation 254 is completed, method 250 proceeds to operation 256 wherein the first integral block performs an integration operation to provide a first output voltage in response to the incident light, while the readout circuit performs the readout operation on the second integral block to output a second output voltage from the second integral block. Once the integration operation 256 of the first operation mode 252 is completed, the photo-detecting apparatus operates in the second operation mode 258. When the photo-detecting apparatus operates in the second operation mode 258, the method 250 includes operation 260 wherein the reset circuit first performs the reset operation on the second integral block. Once the reset operation 260 is completed, the method 250 proceeds to operation 262 wherein the second integral block performs an integration operation to provide a second output voltage in response to the incident light, while the readout circuit performs the readout operation on the first integral block to output the first output voltage from the first integral block. Once the integration operation 262 of the second operation mode 258 is completed, the photo-detecting apparatus operates again in the first operation mode 252. The first operation mode 252 and the second operation mode 258 continue to operate in turn until the detection is completed.

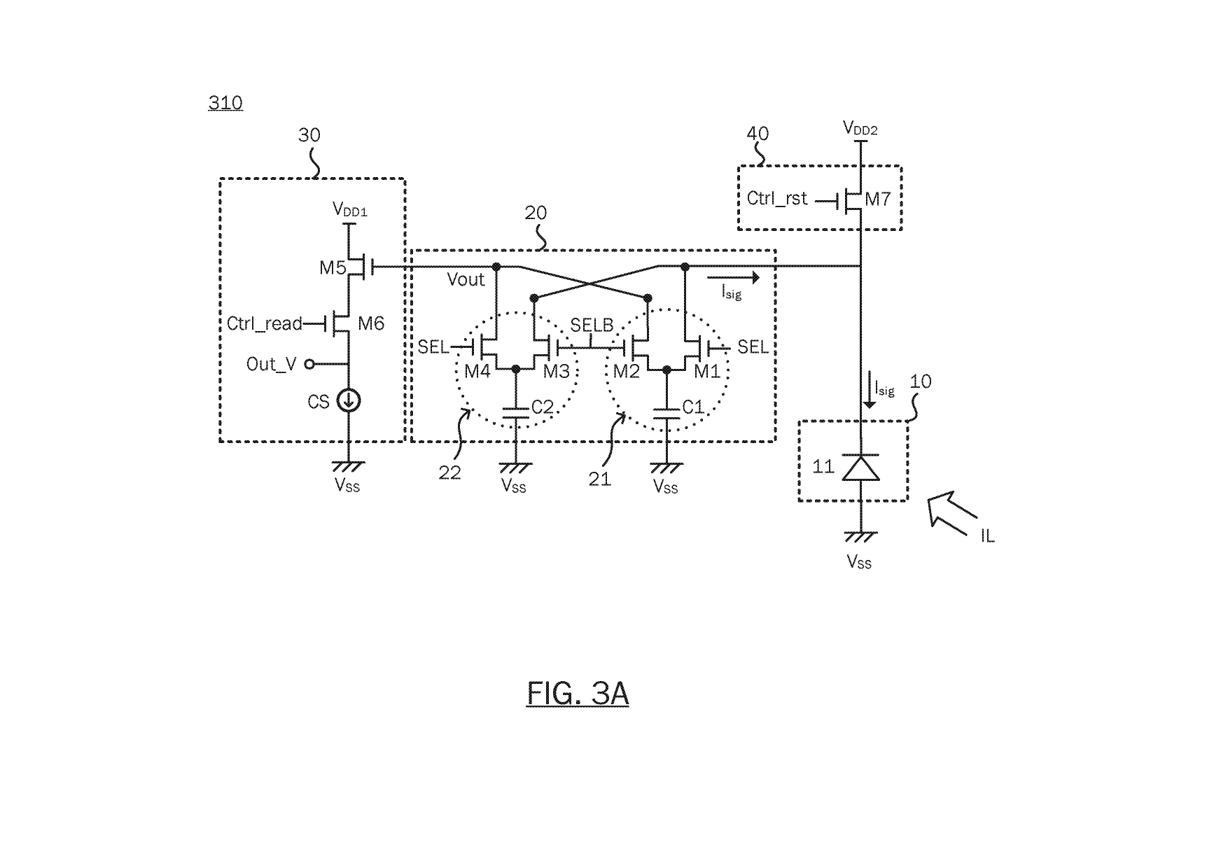

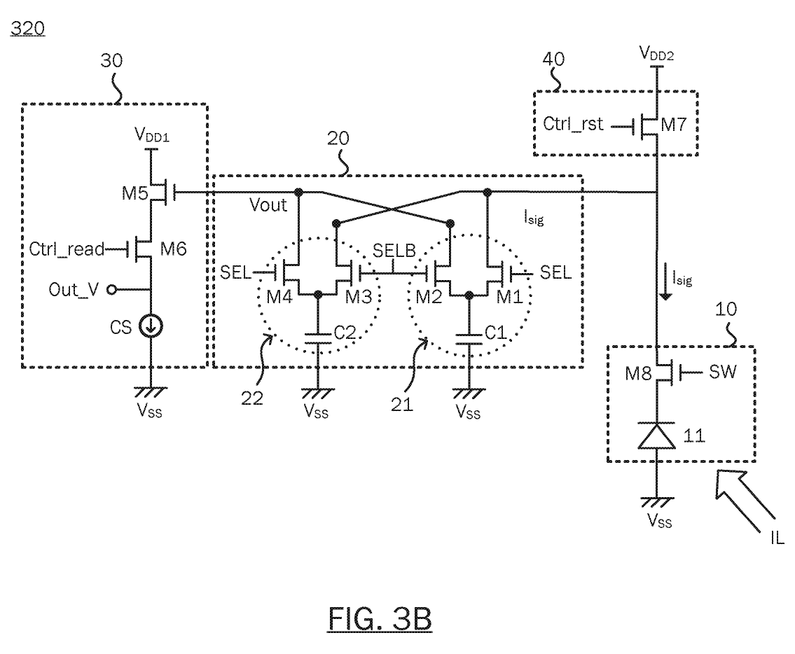

FIG. 3A shows a circuit diagram of a photo-detecting apparatus 310 in accordance with another embodiment of the present disclosure. The light receiver 10 shown in FIG. 1A can be implemented by a photodiode, such as the photodiode 11 in the photo-detecting apparatus 310 of FIG. 3A. The photodiode 11 can include a light-absorption material (e.g., germanium Ge or germanium-silicon GeSi) supported by the semiconductor substrate (e.g., silicon Si or silicon-germanium SiGe). The light- absorption material can use a material different from the semiconductor substrate. In an implementation, the photo-detecting apparatus 310 can be used in 2D sensing applications for sensing image intensity.

FIG. 3B shows a circuit diagram of a photo-detecting apparatus 320 in accordance with another embodiment of the present disclosure. The light receiver 10 shown in FIG. 1A can be implemented by a photodiode and a switch, such as a photodiode 11 and a switch M8 in the photo-detecting apparatus 320 of FIG. 3B. The photo-detecting apparatus 320 is implemented in a one-tap configuration and can be used in 3D sensing applications (e.g., ToF application) or 2D sensing applications (e.g., CMOS image sensor (CIS) application). The switch M8 is configured to output the electrical signal Isig to the converting circuit 20 according to a switch control signal SW. The switch control signal SW is a signal to control the turn-on period of the switch M8. For the 3D sensing applications, the switch control signal SW can be a demodulation signal, allowing the photo-detecting apparatus 320 to obtain the image depth information. For the 2D sensing application, the switch control signal SW can be a non- demodulation signal, allowing the photo-detecting apparatus 320 to obtain the image intensity information. When the switch control signal SW turns on the switch M8 and the incident light comes in, the photodiode 11 generates the electrical signal Isig flowing through the converting circuit 20. In an implementation, the photo-detecting apparatus 320 is used for 2D sensing application and the turns-on period may be a longer period (e.g., 100μs, 500μs, 1ms, 5ms, or similar time scales) to absorb the incident light IL. In another implementation, the photo-detecting apparatus 320 is used for ToF application and the turns-on period may be a shorter demodulation signal (e.g., 3ns, 10ns, 30ns, 100ns, or similar time scales) to absorb the incident light IL.

In one implementation, the switch M8 and the photodiode 11 can be manufactured in the same chip, the reset circuits 40 can be manufactured in another chip. In one implementation, the photodiode 11 can be manufactured in one chip, the switch M8 and the reset circuits 40 can be manufactured in another chip. In one implementation, all the circuits shown in FIG. 3B can be manufactured in the same chip. Furthermore, the light receiver 10 can be implemented by back-side incident (BSI) or front-side incident (FSI), which means the incident light IL can be received from the bottom of the chip or the top of the chip.

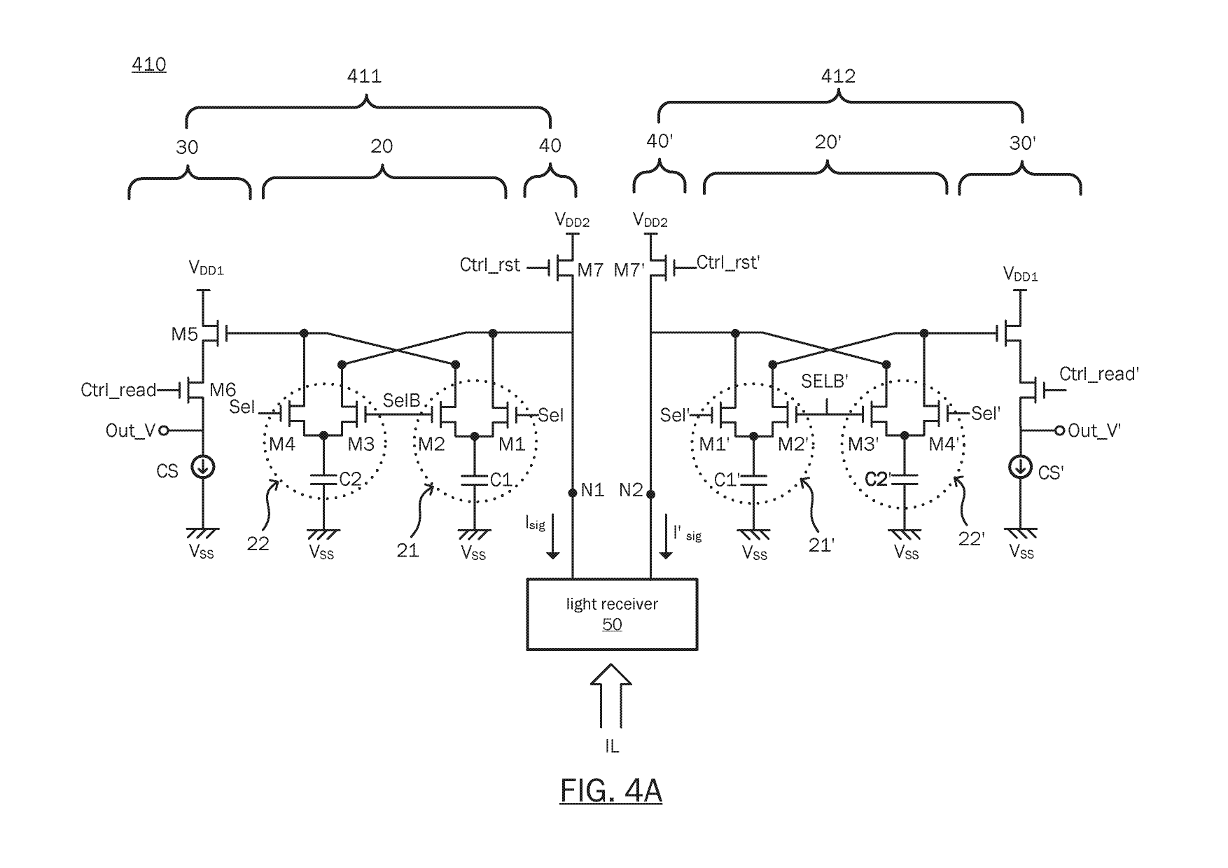

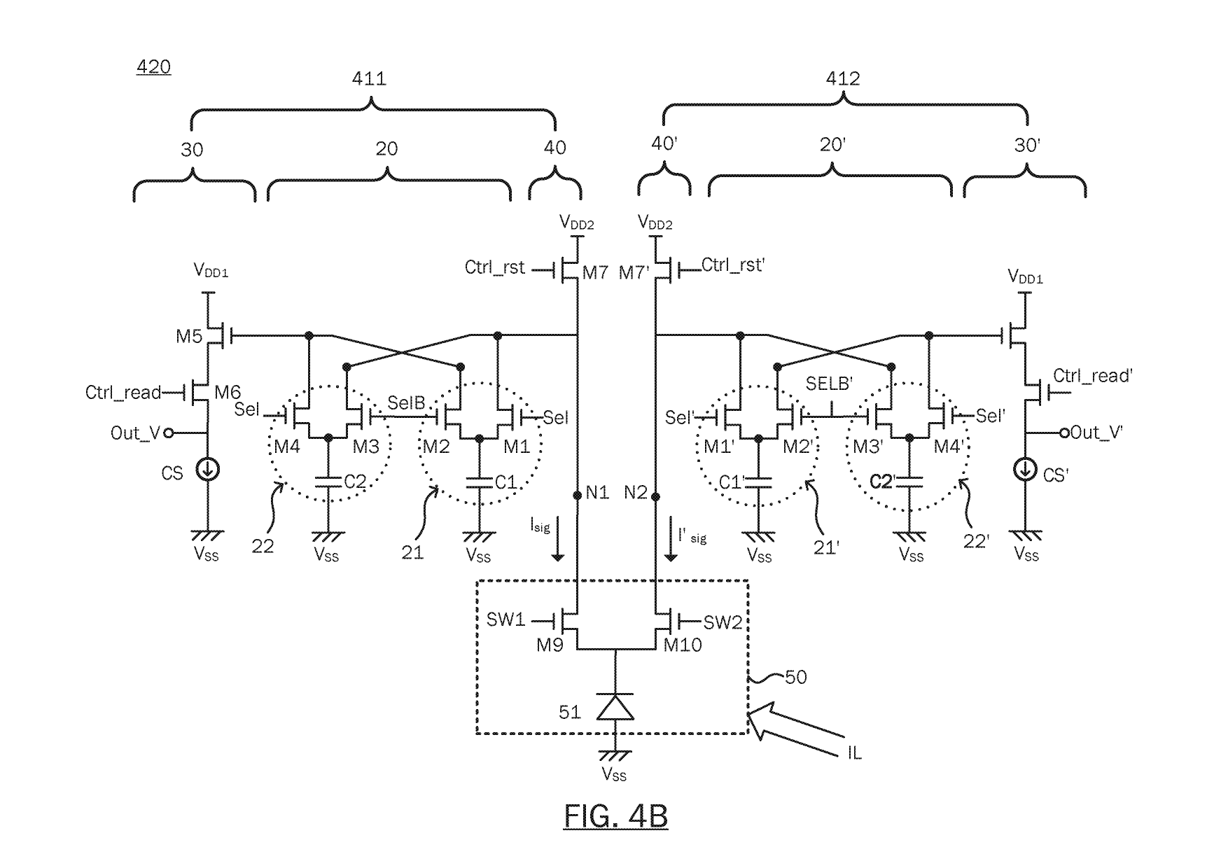

FIG. 4A shows a circuit diagram of a photo-detecting apparatus in accordance with another embodiment of the present disclosure. The photo-detecting apparatus 410 is implemented in a two-tap configuration and can be used in 3D sensing applications (e.g., ToF application) or 2D sensing applications (e.g., CMOS image sensor (CIS) application). Compared to FIGS. 1A-1C and FIGS. 3A-3B, the photo-detecting apparatuses 100, 310, and 320 with one-tap configuration is an unsymmetrical structure, however, the photo-detecting apparatus 410 with a two-tap configuration is a symmetrical structure. The light receiver 50 has a first output terminal N1 and a second output terminal N2 and is configured to convert an incident light IL to an electrical signal Isig at the first output terminal N1 and an electrical signal I’sig at the second output terminal N2, where the electrical signals Isig and I’sig are photo-currents in response to the intensity of the incident light IL. The photo-detecting apparatus 410 includes a first circuit structure 411 and a second circuit structure 412 that are symmetrically arranged. The first circuit structure 411 couples to the first output terminal N1 and is configured to receive the electrical signals Isig. It includes a converting circuit 20, a readout circuit 30, and a reset circuit 40. The converting circuit 20 includes a first integral block 21 and a second integral block 22. The first integral block 21 includes a first capacitor C1, a first transistor M1, and a second transistor M2. The second integral block 22 includes a second capacitor C2, a third transistor M3, and a fourth transistor M4. The readout circuit 30 includes a source-follower transistor M5, a line-select transistor M6, and a current source CS. The reset circuit 40 includes a reset transistor M7.

Similarly, the second circuit structure 412 couples to the second output terminal N2 and is configured to receive the electrical signals I’sig. It includes a converting circuit 20’, a readout circuit 30’, and a reset circuit 40’. The converting circuit 20’ includes a first integral block 21’ and a second integral block 22’. The first integral block 21’ includes a first capacitor C1’, a first transistor M1’, and a second transistor M2’. The second integral block 22’ includes a second capacitor C2’, a third transistor M3’, and a fourth transistor M4’. The readout circuit 30’ includes a source-follower transistor M5’, a line-select transistor M6’, and a current source CS’. The reset circuit 40’ includes a reset transistor M7’. The configurations and functions of the converting circuits 20 and 20', the readout circuits 30 and 30', and the reset circuits 40 and 40' are the same as the corresponding circuits in FIG. 1A, and the detailed descriptions can refer to the corresponding descriptions in FIG. 1A. Similar to the photo-detecting apparatus 100 in FIG. 1A, the converting circuits 20, and 20' coupling to each output terminals of the light receiver 50 has at least two integral blocks (e.g., 21 and 22, 21' and 22') for performing integration operation and readout operation in turn. Therefore, the photo-detecting apparatus 410 can simultaneously perform the integration operation and the readout operation to achieve high-speed detection.

During the reset operation on the converting circuit 20, the first capacitor C1 and the second capacitor C2 of the converting circuit 20 would be charged to the source voltage VDD2 by the reset circuit 40. Similarly, during the reset operation on the converting circuit 20', the first capacitor C1' and the second capacitor C2' of the converting circuit 20' would be charged to the source voltage VDD2 by the reset circuit 40'. When the electrical signal Isig is generated at the first output terminal N1 due to the incident light IL, the converting circuit 20 of the first circuit structure 411 performs the integration operation. During the integration operation, the first capacitor C1 and the second capacitor C2 of converting circuit 20 will be discharged from the source voltage VDD2 in turn. At the same time, the readout circuit 30 also performs a readout operation on the converting circuit 20 to transmit the output voltages of the first integral block 21 and the second integral block 22 to the terminal Out_V in turn. When the electrical signal I'sig is generated at the second output terminal N2 due to the incident light IL, the converting circuit 20' of the second circuit structure 412 performs the integration operation. During the integration operation, the first capacitor C1' and the second capacitor C2' of converting circuit 20' will be discharged from the source voltage VDD2 in turn. At the same time, the readout circuit 30' also performs a readout operation on the converting circuit 20' to transmit the output voltages of the first integral block 21' and the second integral block 22' to the terminal Out_V' in turn.

FIG. 4B shows a circuit diagram of a photo-detecting apparatus 420 in accordance with another embodiment of the present disclosure. The light receiver 50 shown in FIG. 4A can be implemented by a photodiode and two switches, such as the photodiode 51, a first switch M9, and a second switch M10 in the photo-detecting apparatus 420 of FIG. 4B. The first switch M9 is configured to output the electrical signal Isig to the converting circuit 20 according to a first switch control signal SW1. The first switch control signal SW1 is a signal to control the turns-on period of the first switch M9. The second switch M10 is configured to output the electrical signal I’sig to the converting circuit 20’ according to a second switch control signal SW2. The second switch control signal SW2 is a signal to control the turn-on period of the second switch M10. The electrical signal Isig and the electrical signal I’sig are generated according to the first switch control signal SW1 and the second switch control signal SW2. In one implementation, the first switch control signal SW1 and the second switch control signal SW2 are demodulation signals. In another implementation, the first switch control signal SW1 and the second switch control signal SW2 are different from each other. In another implementation, the first switch control signal SW1 and the second switch control signal SW2 use clock signals with a 50% duty cycle. In other possible implementations, the duty cycle can be different (e.g., 30% duty cycle). In some implementations, a square wave is used as the modulation and demodulation signals. In some implementations, a sinusoidal wave is used as the modulation and demodulation signals instead of square wave.

The photo-detecting apparatuses 410 and 420 can be used in 3D sensing applications (e.g., ToF applications) or 2D sensing applications (e.g., CIS applications). For the 3D sensing applications, the first switch control signal SW1 and the second switch control signal SW2 can include demodulation signals, allowing the photo-detecting apparatuses 410 or 420 to obtain the image depth information. For the2D sensing applications, the first switch control signal SW1 and the second switch control signal SW2 can be a non-demodulation signal, allowing the photo-detecting apparatuses 410 or 420 to obtain the image intensity information.

In one implementation, the switches M9, M10, and the photodiode 51 can be manufactured in the same chip, the reset circuits 40, 40' can be manufactured in another chip. In one implementation, the photodiode 51 can be manufactured in one chip, the switches M9, M10, and the reset circuits 40, 40' can be manufactured in another chip. In one implementation, all the circuits shown in FIG. 4B can be manufactured in the same chip. Furthermore, the light receiver 50 can be implemented by back-side incident (BSI) or front-side incident (FSI), which means the incident light IL can be received from the bottom of the chip or the top of the chip.

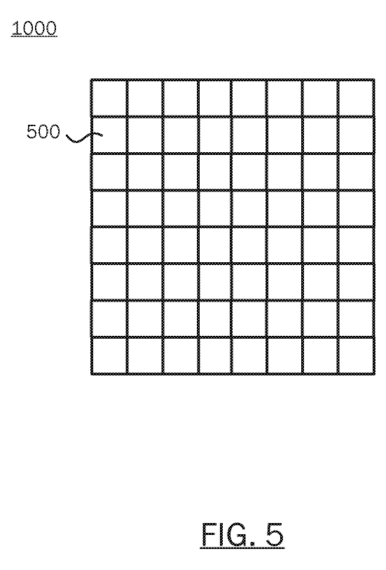

FIG. 5 shows an image sensor in accordance with an embodiment of the present disclosure. The image sensor 1000 can detect ambient light, reflected light from objects, or perform 2D or 3D sensing of objects. The image sensor 1000 includes a plurality of photo-detecting apparatuses 500 to collectively form a pixel array. Each photo-detecting apparatus 500 can be one of the aforementioned implementations. The image sensor 1000 can be widely used in many electronic devices such as a digital still camera, a smartphone, a video camera, a vehicle camera, or a camera drone to obtain 2-dimensional (2D) and3-dimensional (3D) information.

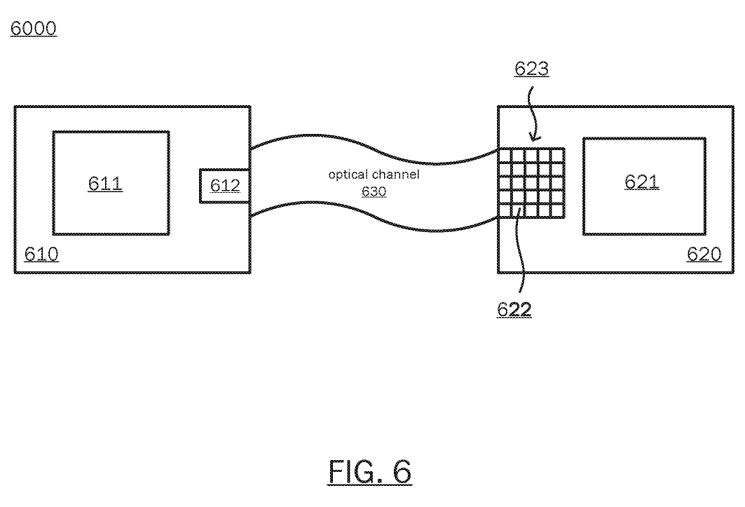

FIG. 6 shows an optical communication system in accordance with an embodiment of the present disclosure. The optical communication system 6000 includes an optical transmitting module 610, an optical receiving module 620, and an optical channel 630 coupling to the optical transmitting module 610 and the optical receiving module 620. The optical transmitting module 610 includes a light transmitter 612 to transmit at least one optical signal and a transmitting controller 611 configured to control the plurality of light transmitters 612. The light transmitter 612 can be a light- emitting diode (LED), a laser diode, a vertical-cavity surface-emitting laser (VCSEL), or organic light-emitting diode (OLED). In an embodiment, the light transmitter 612 can include a plurality of light sources (e.g., LED, VCSEL, microLED, OLED) to form an array. The optical receiving module 620 includes a plurality of photo-detecting apparatuses 622 collectively formed an array 623 to receive at least one optical signal from the optical channel 630 and a receiving controller 621 configured to control the plurality of photo-detecting apparatuses 622. The photo-detecting apparatus 622 can be one of the aforementioned implementations. The optical channel 630 can include at least one waveguide, at least one fiber, or air.

The foregoing embodiments illustrate the photo-detecting apparatuses with either one-tap configuration or two-tap configuration. In some implementations, the tap number can be more than two. One may implement a 4-tap or more to configure a photo-detecting apparatus based on different design requirements.

The transistors mentioned in the disclosure embodiments use MOSFET as an example in the drawings. The reset pins (pins other than drain, gate, and source) are not explicitly shown in the drawings, due to the other pins can be connected to arbitrary points that sustain a transistor behavior and do not cause reliability issues or unintentional current leakage.

Various means can be configured to perform the methods, operations, and processes described herein. For example, any of the systems and apparatuses (e.g., optical sensor devices and related circuitry) can include unit(s) and/or other means for performing their operations and functions described herein. In some implementations, one or more of the units may be implemented separately. In some implementations, one or more units may be a part of or included in one or more other units. These means can include processor(s), microprocessor(s), graphics processing unit(s), logic circuit(s), dedicated circuit(s), application-specific integrated circuit(s), programmable array logic, field-programmable gate array(s), controller(s), microcontroller(s), and/or other suitable hardware. The means can also, or alternately, include software control means implemented with a processor or logic circuitry, for example. The means can include or otherwise be able to access memory such as, for example, one or more non-transitory computer-readable storage media, such as random-access memory, read-only memory, electrically erasable programmable read-only memory, erasable programmable read-only memory, flash/other memory device(s), data register(s), database(s), and/or other suitable hardware.

As used herein, the terms such as “first”, “second”, “third”, etc. describe various elements, components, regions, layers and/or sections, these elements, components, regions, layers and/or sections should not be limited by these terms. These terms may be only used to distinguish one element, component, region, layer, section, signal, or operation from another. The terms such as “first”, “second”, “third”, etc. when used herein do not imply a sequence or order unless clearly indicated by the context. The terms “light-receiving”, “light-detecting”, “light-sensing” and any other similar terms can be used interchangeably.

Aspects of the disclosure have been described in terms of illustrative embodiments thereof. Numerous other embodiments, modifications, and/or variations within the scope and spirit of the appended claims can occur to persons of ordinary skill in the art from a review of this disclosure. Any and all features in the following claims can be combined and/or rearranged in any way possible. Accordingly, the scope of the present disclosure is by way of example rather than by way of limitation, and the subject disclosure does not preclude inclusion of such modifications, variations or additions to the present subject matter as would be readily apparent to one of ordinary skill in the art. Moreover, terms are described herein using lists of example elements joined by conjunctions such as “and,” “or,” “but,” etc. It should be understood that such conjunctions are provided for explanatory purposes only. Lists joined by a particular conjunction such as “or,” for example, can refer to “at least one of” or “any combination of” example elements listed therein. Also, terms such as “based on” should be understood as “based at least in part on”.

Those of ordinary skill in the art, using the disclosures provided herein, will understand that the elements of any of the claims discussed herein can be adapted, rearranged, expanded, omitted, combined, or modified in various ways without deviating from the scope of the present disclosure.

While the disclosure has been described by way of example and in terms of a preferred embodiment, it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A photo-detecting apparatus, comprising:
a light receiver configured to convert an incident light to an electrical signal;
a converting circuit coupling to the light receiver to convert the electrical signal into an output voltage through an integration operation, wherein the converting circuit comprises a first integral block and a second integral block; and
a readout circuit coupling to the converting circuit to output the output voltage from the converting circuit,
wherein while the first integral block has an electrical connection to the light receiver to perform the integration operation, the second integral block has an electrical connection to the readout circuit to output the output voltage,
wherein while the first integral block has an electrical connection to the readout circuit to output the output voltage, the second integral block has an electrical connection to the light receiver to perform the integration operation.

2. The photo-detecting apparatus of claim 1, further comprising a first integral control signal and a second integral control signal applying to the converting circuit to control the electrical connection of the first integral block and the electrical connection of the second integral block.

3. The photo-detecting apparatus of claim 2, wherein the second integral control signal has an opposite polarity to the first integral control signal.

4. The photo-detecting apparatus of claim 2, wherein the first integral block comprises a first capacitor, and the first capacitor is configured to electrically connect to the light receiver through a first transistor according to the first integral control signal.

5. The photo-detecting apparatus of claim 2, wherein the first integral block comprises a first capacitor, and the first capacitor is configured to electrically connect to the readout circuit through a second transistor according to the second integral control signal.

6. The photo-detecting apparatus of claim 2, wherein the second integral block comprises a second capacitor, and the second capacitor is configured to electrically connect to the light receiver through a third transistor according to the second integral control signal.

7. The photo-detecting apparatus of claim 2, wherein the second integral block comprises a second capacitor, and the second capacitor is configured to electrically connect to the readout circuit through a fourth transistor according to the first integral control signal.

8. The photo-detecting apparatus of claim 1, wherein the readout circuit comprises a source-follower transistor coupling to the converting circuit to receive the output voltage and a line-select transistor coupling to the source-follower transistor to output the output voltage.

9. The photo-detecting apparatus of claim 8, wherein the line-select transistor comprises a first node coupling to the source-follower transistor, a second node configured to output the output voltage, and a third node configured to receive a readout control signal to determine whether the readout circuit outputs the output voltage from the converting circuit.

10. The photo-detecting apparatus of claim 1, further comprising a reset circuit coupling to the converting circuit to reset the converting circuit before each integration operation.

11. The photo-detecting apparatus of claim 1, wherein the light receiver comprises a photodiode configured to absorb the incident light and a switch configured to output the electrical signal.

12. The photo-detecting apparatus of claim 11, wherein the photodiode comprises a light-absorption material supported by a semiconductor substrate, and the light- absorption material is different from a material of the semiconductor substrate.

13. A method of using a photo-detecting apparatus to detect an incident light, the photo-detecting apparatus comprising a reset circuit, a first integral block, a second integral block, and a readout circuit, wherein the method comprises:
entering a first operation mode, the first operation mode comprising:
performing, by the reset circuit, a reset operation on the first integral block;
and
performing, by the first integral block, an integration operation to provide a first output voltage in response to the incident light, while the readout circuit outputs a second output voltage from the second integral block; and
entering a second operation mode, the second operation mode comprising:
performing, by the reset circuit, the reset operation on the second integral block; and
performing, by the second integral block, the integration operation to provide the second output voltage in response to the incident light, while the readout circuit outputs the first output voltage from the first integral block.

14. The method of claim 13, wherein the reset operation is controlled by a reset control signal.

15. The method of claim 13, wherein the first integral block comprises a first capacitor, the reset operation comprises charging the first capacitor to a source voltage.

16. The method of claim 15, wherein the integration operation comprises discharging the first capacitor from the source voltage to the first output voltage.

17. The method of claim 13, wherein the first operation mode comprises electrically connecting the first integral block to a light receiver and the reset circuit, and electrically connecting the second integral block to the readout circuit.

18. The method of claim 13, wherein the second operation mode comprises electrically connecting the second integral block to a light receiver and the reset circuit, and electrically connecting the first integral block to the readout circuit.

19. An optical communication system comprising:
an optical channel configured to transmit a plurality of optical signals; and
an optical receiving module comprising a plurality of photo-detecting apparatuses of claim 1 to receive the plurality of optical signals.

20. The optical communication system of claim 19, further comprising a plurality of light transmitters coupling to the optical channel to transmit the plurality of optical signals.
